(19) United States
(12) Patent Application Publication
(10) Pub. No.: US 2022/0386503 A1
(43) Pub. Date: Dec. 1, 2022

(54) OPTICAL TRANSCEIVER WITH HOUSING PRESSING THERMAL INTERFACE MATERIAL BY UNEVEN SURFACE

(71) Applicant: Prime World International Holdings Ltd., New Taipei City (TW)

(72) Inventors: Che-Shou YEH, New Taipei City (TW); Ming-You LAI, New Taipei City (TW); Ling-An KUNG, New Taipei City (TW)

(21) Appl. No.: 17/331,560

(22) Filed: May 26, 2021

(51) Int. Cl. H05K 7/20; H05K 1/02; H04B 10/40

(52) U.S. Cl. CPC H05K 7/2049; H05K 1/0203; H05K 7/20463; H04B 10/40

(57) ABSTRACT

An optical transceiver includes a housing, a heat source accommodated in the housing, and a thermal interface material accommodated in the housing. The housing is in thermal contact with the heat source through the thermal interface material, and the thermal interface material is in physical contact with an uneven surface of the housing.

### BACKGROUND

### 1. Technical Field

The present disclosure relates to optical communication, more particularly to an optical transceiver.

### 2. Related Art

Optical transceivers are generally installed in electronic communication facilities in modern high-speed communication networks. In order to make flexible the design of an electronic communication facility and less burdensome the maintenance of the same, an optical transceiver is inserted into a corresponding cage that is disposed in the communication facility in a pluggable manner. In order to define the electrical-to-mechanical interface of the optical transceiver and the corresponding cage, different form factors such as XFP (10 Gigabit Small Form Factor Pluggable) used in 10 GB/s communication rate, QSFP (Quad Small Form-factor Pluggable), or others at different communication rates have been made available.

As to the optical components in a conventional optical transceiver, a circuit board is disposed in a housing, and a TOSA (Transmitter optical sub-assembly) as well as a ROSA (Receiver optical sub-assembly) are mounted on the circuit board.

### BRIEF DESCRIPTION OF THE DRAWINGS

The present disclosure will become more fully understood from the detailed description given below and the accompanying drawings which are given by way of illustration only and thus are not intending to limit the present disclosure and wherein:

FIG. 1 is a perspective view of an optical transceiver according to one embodiment of the present disclosure;

FIG. 2 is an exploded view of the optical transceiver in FIG. 1;

FIG. 3 is a cross-sectional view of the optical transceiver in FIG. 1;

FIG. 4 is a partially enlarged view of the optical transceiver in FIG. 3 with non-compressed thermal interface material;

FIG. 5 is a partially enlarged view of the optical transceiver in FIG. 3;

FIG. 6 is a schematic view showing heat transfer path of the optical transceiver in FIG. 3;

FIG. 7 is a cross-sectional view of an optical transceiver according to another embodiment of the present disclosure; and

FIG. 8 is a schematic view showing the optical transceiver in FIG. 1 which is inserted into a cage.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

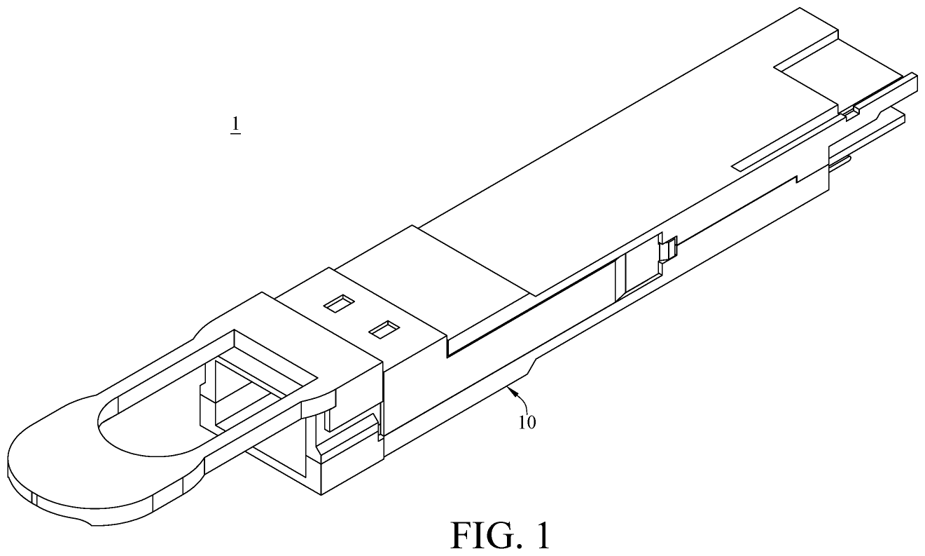

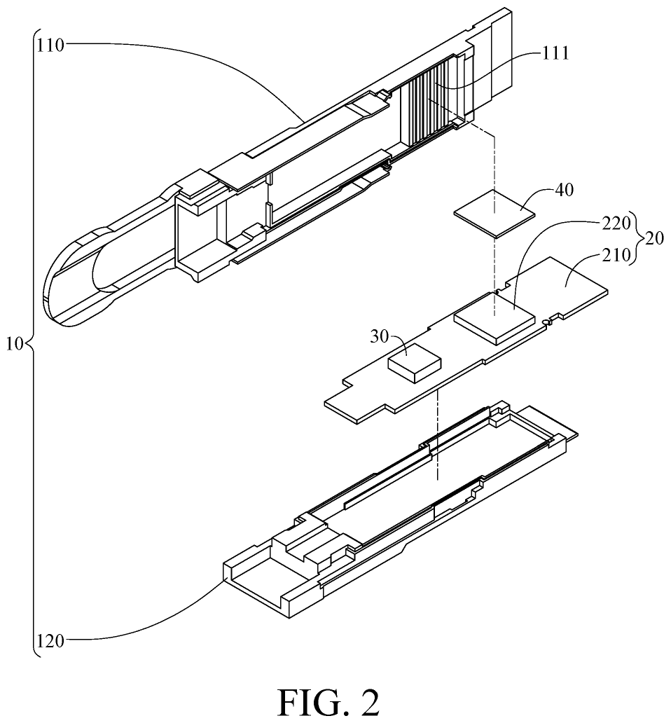

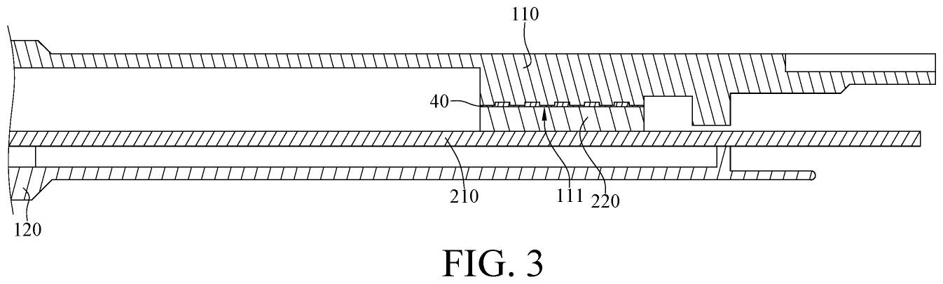

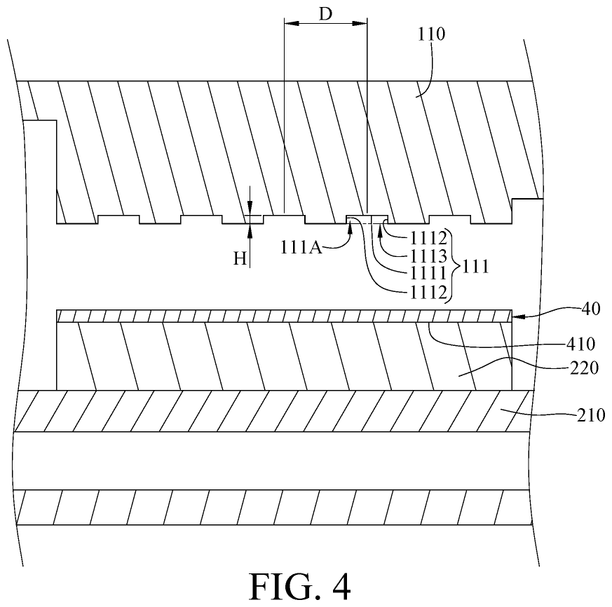

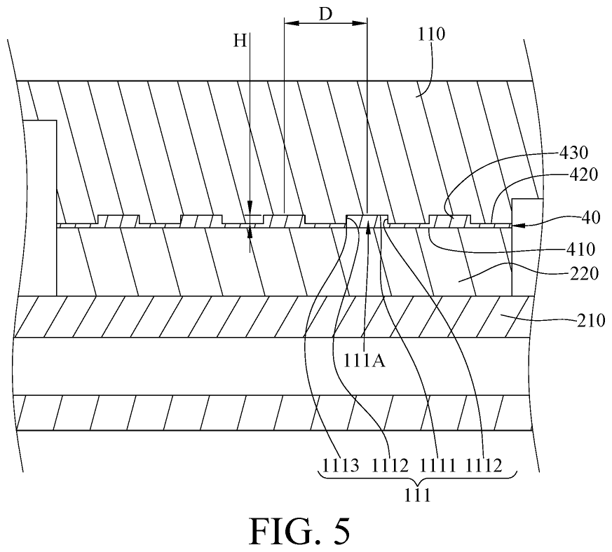

Please refer to FIG. 1 through FIG. 5 FIG. 1 is a perspective view of an optical transceiver according to one embodiment of the present disclosure. FIG. 2 is an exploded view of the optical transceiver in FIG. 1. FIG. 3 is a cross-sectional view of the optical transceiver in FIG. 1. FIG. 4 is a partially enlarged view of the optical transceiver in FIG. 3 with non-compressed thermal interface material. FIG. 5 is a partially enlarged view of the optical transceiver in FIG. 3. In this embodiment, an optical transceiver 1 may include a housing 10, a circuit board 20, an optical communication module 30 and a thermal interface material 40.

The housing 10 includes an upper cover 110 and a lower cover 120 which are assembled together. The housing 10 may be configured to be inserted into a cage in pluggable manner for optical communication.

The circuit board 20 is accommodated in the housing 10, and includes a substrate 210 and a heat source 220. In this embodiment, the heat source 220 is a high power IC chip which generates a large amount of heat during its operation and the high power IC chip is mounted on the substrate 210. It is worth noting that several other components may become the heat source 220 as discussed in the present disclosure.

The optical communication module 30 may be a TOSA or a ROSA accommodated in the housing 10. The optical communication module 30 includes one or more optical communication components disposed on the substrate 210 of the circuit board 20. The optical communication component of the optical communication module 30 may be a laser diode or a photodiode electrically connected to the high power IC chip (heat source 220) of the circuit board 20.

The thermal interface material 40, for example, is a thermal pad, a thermal paste or a thermal gel accommodated in the housing 10, and the thermal interface material 40 is in physical contact with an uneven surface of the housing 10 which is discussed in more detail later. More specifically, as shown in FIG. 3 through FIG. 5, the upper cover 110 of the housing 10 includes an uneven surface 111 which might be implemented to include several protruding portions and cavities facing toward the thermal interface material 40, and the uneven surface 111 (or the protruding portions thereof) touches the thermal interface material 40. The housing 10 is in thermal contact with the heat source 220 through the thermal interface material 40. The thermal interface material 40 is located on a side of the heat source 220 opposite to the substrate 210. The thermal interface material 40 is located between the heat source 220 and part of the upper cover 110, and the heat source 220 is located between the thermal interface material 40 and part of the lower cover 120. Opposite sides of the thermal interface material 40 are in physical contact with the uneven surface 111 of the housing 10 and the heat source 220, respectively. More specifically, the thermal interface material 40 includes opposite surfaces 410 and 420, the surface 410 is in physical contact with the heat source 220, and the surface 420 is in physical contact with the thermal interface material 40. It is worth noting that the position of uneven surface 111 is not limited by this embodiment; in some cases, the heat source and the thermal interface material are located below the substrate, and an uneven surface in contact with the thermal interface material can be the inner surface of the lower cover facing the upper cover.

The thermal interface material 40 is compressed between the uneven surface 111 of the housing 10 and the heat source 220. As shown in FIG. 4 and FIG. 5, the housing 10 includes multiple recesses 111A on the uneven surface 111, and each recess 111A extends away from the thermal interface material 40. As to each recess 111A, a portion 430 of the thermal interface material 40 is in the recess 111A. More specifically, the housing 10 presses the thermal interface material 40 to make at least part of the thermal interface material 40 deform, the portion 430 of the deformed thermal interface material 40 is filled entirely or partially within the recess 111A through an opening 1113 of the recess 111A, and another portion of the deformed thermal interface material 40 is pressed by a flat area of the uneven surface 111. It is worth noting that the recess might be considered as the cavity while the flat area could be treated as the protruding portion with respect to the cavity. The portion 430 of the thermal interface material 40 is in physical contact with each surface of the recess 111A. More specifically, each recess 111A is defined by a bottom surface 1111 and two lateral surfaces 1112. It is worth noting that the number of recesses 111A is not limited by the present disclosure.

In this embodiment, the vertical distance H between the bottom surface 1111 of the recess 111A and the opening 1113 of the recess 111A may be less than or equal to 0.2 millimeter (mm), such that it is helpful to prevent stress concentration in the compressed thermal interface material 40. Furthermore, for a pair of adjacent recesses 111A, the pitch D of the two recesses 111A may be greater than or equal to 1 mm, such that the structure on the uneven surface 111 of the housing 10 can be fabricated by commercial CNC machine, which is helpful to mass production.

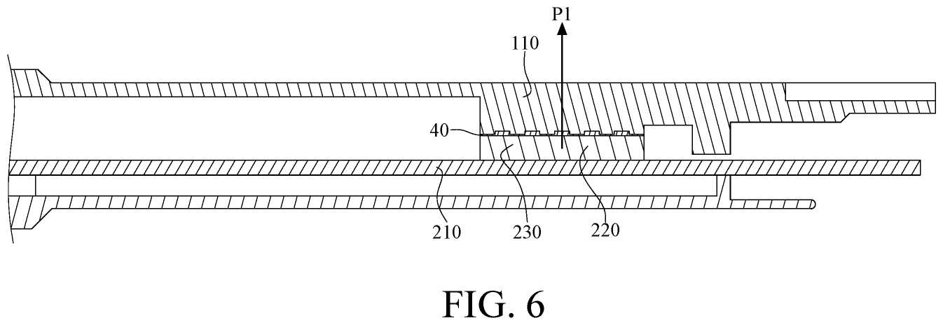

FIG. 6 is a schematic view showing heat transfer path of the optical transceiver in FIG. 3. A symbol P1 represents a heat transfer path from the heat source 220 to the upper cover 110 of the housing 10. The heat source 220 generates heat during its operation, and such heat is transferred through the thermal interface material 40 to reach the upper cover 110 (path P1).

With the pressed thermal interface material 40, the compressed thermal interface material 40 enjoys better heat dissipation performance. For example, some portions of the thermal interface material 40 in the recesses 111A are slightly compressed, and some other portions of the thermal interface material 40 outside the recesses 111A can be compressed significantly. Also, compared to a conventional optical transceiver in which the thermal interface material is pressed by a flat inner surface of the housing, the lateral surfaces 1112 of each recess 111A on the uneven surface 111 of the housing 10 in this embodiment provide additional heat exchange area, which helps the heat dissipation efficiency.

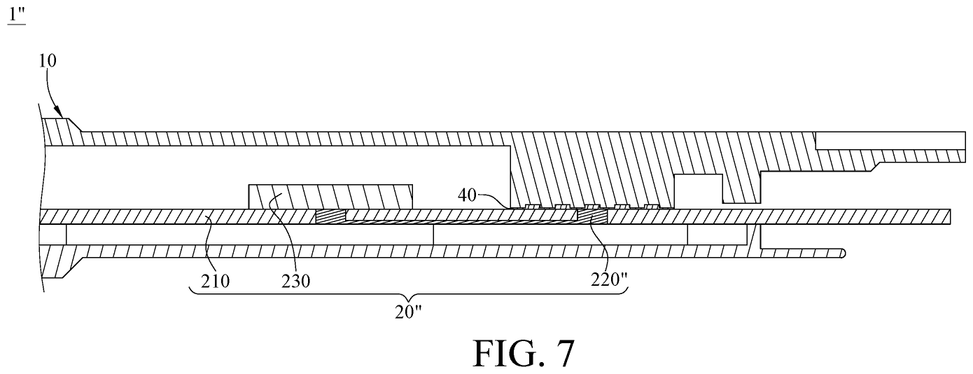

FIG. 7 is a cross-sectional view of an optical transceiver according to another embodiment of the present disclosure. In this embodiment, an optical transceiver 1″ may include a housing 10, a circuit board 20″ and a thermal interface material 40. The housing 10 and the thermal interface material 40 may be similar to their counterparts in FIG. 3.

The circuit board 20″ includes a substrate 210 and a heat source 220″. In this embodiment, the heat source 220″ is a thermal via in the substrate 210, and the thermal via may be a metal bar filled in a drilled through hole of the substrate 210 or a metal film coated on the inner wall of said drilled through hole. The thermal via is in thermal connection with one or more components 230 such as high power IC chip or photodiode generating a large amount of heat during its operation. The thermal interface material 40 is compressed between the uneven surface 111 of the housing 10 and the heat source 220″. The housing 10 is in thermal contact with the heat source 220″ through the thermal interface material 40.

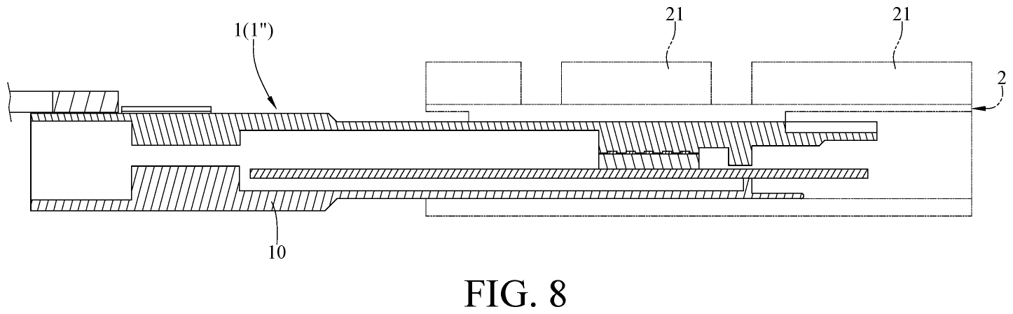

FIG. 8 is a schematic view showing the optical transceiver in FIG. 1 which is inserted into a cage. The optical transceiver 1 or 1″ can be inserted to a corresponding port/slot of a cage 2 with one located below another. The cage 2 includes multiple fins 21 extending from the top surface of the cage 2. The fins 21 are configured as a heat sink in thermal contact with the housing 10.

According to the present disclosure, the housing is in thermal contact with the heat source through the thermal interface material, and the thermal interface material is in physical contact with an uneven surface of the housing. Compared to a conventional optical transceiver in which the thermal interface material is pressed by a flat inner surface of the housing, structures on the uneven surface of the housing provide additional heat exchange area, which helps the heat dissipation efficiency.

The embodiments are chosen and described in order to best explain the principles of the present disclosure and its practical applications, to thereby enable others skilled in the art to best utilize the present disclosure and various embodiments with various modifications as are suited to the particular use being contemplated. It is intended that the scope of the present disclosure is defined by the following claims and their equivalents.

What is claimed is:

1. An optical transceiver, comprising:
a housing;
a heat source accommodated in the housing; and
a thermal interface material accommodated in the housing, wherein the housing is in thermal contact with the heat source through the thermal interface material, and the thermal interface material is in physical contact with an uneven surface of the housing.

2. The optical transceiver according to claim 1, wherein the housing comprises an upper cover and a lower cover assembled together, the thermal interface material is located between the heat source and part of the upper cover, the heat source is located between the thermal interface material and part of the lower cover, and an inner surface of the upper cover is the uneven surface of the housing.

3. The optical transceiver according to claim 1, wherein opposite sides of the thermal interface material are in physical contact with the uneven surface of the housing and the heat source, respectively.

4. The optical transceiver according to claim 1, wherein the housing comprises at least one recess on the uneven surface, and a portion of the thermal interface material is in the at least one recess.

5. The optical transceiver according to claim 4, wherein the thermal interface material is pressed by the housing, and the portion of the thermal interface material is entirely or partially filled within the at least one recess.

6. The optical transceiver according to claim 4, wherein the portion of the thermal interface material is in physical contact with a bottom surface and a lateral surface of the at least one recess.

7. The optical transceiver according to claim 1, wherein the thermal interface material is a thermal pad compressed between the housing and the heat source.

8. The optical transceiver according to claim 1, further comprising a circuit board accommodated in the housing, wherein the circuit board comprises a substrate and the heat source mounted on the substrate, and the thermal interface material is located on a side of the heat source opposite to the substrate.

9. The optical transceiver according to claim 8, wherein the heat source is an IC chip or a thermal via of the circuit board.

10. An optical transceiver, comprising:
a housing comprising an uneven surface;
a heat source accommodated in the housing; and
a thermal interface material disposed between the housing and the heat source, wherein the housing is in thermal contact with the heat source through the thermal interface material, and the thermal interface material is compressed between the uneven surface of the housing and the heat source.

11. The optical transceiver according to claim 10, wherein the housing comprises an upper cover and a lower cover assembled together, the thermal interface material is located between the heat source and part of the upper cover, the heat source is located between the thermal interface material and part of the lower cover, and an inner surface of the upper cover is the uneven surface of the housing.

12. The optical transceiver according to claim 10, wherein opposite sides of the thermal interface material are in physical contact with the uneven surface of the housing and the heat source, respectively.

13. The optical transceiver according to claim 10, wherein the housing comprises at least one recess on the uneven surface, and a portion of the thermal interface material is in the at least one recess.

14. The optical transceiver according to claim 13, wherein the thermal interface material is pressed by the housing, and the portion of the thermal interface material is entirely or partially filled within the at least one recess.

15. The optical transceiver according to claim 13, wherein the portion of the thermal interface material is in physical contact with a bottom surface and a lateral surface of the at least one recess.

16. The optical transceiver according to claim 10, wherein the thermal interface material is a thermal pad compressed between the housing and the heat source.

17. The optical transceiver according to claim 10, further comprising a circuit board accommodated in the housing, wherein the circuit board comprises a substrate and the heat source, and the heat source is an IC chip mounted on the substrate or a thermal via filled in the substrate.

18. A housing for optical transceiver, comprising an inner surface configured to face toward a thermal interface material, wherein the inner surface comprises at least one recess configured to accommodate a portion of the thermal interface material.
